(19) United States
(12) Patent Application Publication
(10) Pub. No.: US 2006/0278985 A1
(43) Pub. Date: Dec. 14, 2006

(54) Multilevel semiconductor devices and methods of manufacturing the same

(76) Inventors: Hyunseok Lim, Suwon-City (KR); Jisoon Park, Gyeonggi-Do (KR); Dongjo Kang, Suwon-City (KR); Jungwook Kim, Yongin-City (KR); Insun Park, Seoul (KR); Hyunsuk Lee, Suwon-City (KR)

Correspondence Address: LEE & MORSE, P.C., 3141 FAIRVIEW PARK DRIVE, SUITE 500, FALLS CHURCH, VA, 22042, US

(21) Appl. No.: 11/312,441

(22) Filed: Dec. 21, 2005

(30) Foreign Application Priority Data
Jun. 9, 2005 (KR) 2005-0049387

(51) Int. Cl. H01L 23/48

(52) U.S. Cl. 257/741

(57) ABSTRACT

A multilevel semiconductor device and method of making the same includes a first active semiconductor structure, a first insulating layer on the first active semiconductor structure, a second active semiconductor structure on the first insulating layer and over the first active semiconductor structure, a second insulating layer on the second active semiconductor structure, and a contact structure including a first ohmic contact having a vertical thickness on an upper surface of the first active semiconductor structure and a second ohmic contact of a lateral thickness on a sidewall of the second active semiconductor structure, the vertical thickness being greater than the lateral thickness.

### BACKGROUND OF THE INVENTION

1. Field of the Invention

The present invention is directed to a semiconductor device and a method of manufacturing the same. In particular, the present invention is directed to a multilevel semiconductor device and a method of manufacturing the same, the multilevel semiconductor device having a first active semiconductor structure, a second active semiconductor structure, formed above the first active semiconductor structure, and a conductive region coupling the first and second active semiconductor structures, wherein the conductive region is in ohmic contact with source/drain regions of the first and second active semiconductor structures.

2. Description of the Related Art

The evolution of integrated circuits has been driven by three principal objectives: reducing size, lowering power consumption and increasing operation speed. The increasing speed and complexity of integrated circuits has made necessary multiple small, closely-spaced transistors within a single integrated circuit. Transistors are generally formed within the silicon-based substrate of an integrated circuit. Traditionally, the number of transistors per integrated circuit has been limited by the available surface area of the substrate. Accordingly, efforts have been directed to increasing the level of integration of integrated circuits by forming multilevel devices having transistors on two or more levels.

Multilevel devices having transistors on two or more levels may include transistors located on the substrate as well as transistors located on a layer above the substrate. For example, transistors may be formed on the silicon substrate as well as on an interlayer dielectric (ILD) layer formed on the bottom transistor. An elevated substrate may be formed on the ILD layer and an upper transistor may be formed on the elevated substrate.

Wiring may then be provided to connect transistors on the silicon substrate with transistors on the elevated substrate. For example, wiring may formed on, i.e., vertical to, a source/drain region of a transistor formed on the substrate and lateral to a source/drain region of a transistor on the elevated substrate.

It is important that ohmic contact regions formed where the wiring contacts the source/drain regions having a sufficiently low resistance that the current passing therethrough allows the device to operate. Further, it may be important that the thickness of an ohmic contact region for a transistor on the substrate is different from the thickness of an ohmic contact region for a transistor formed on the elevated substrate. However, obtaining different thicknesses for these regions is not readily achievable using conventional methods.

### SUMMARY OF THE INVENTION

The present invention is therefore directed to multilevel semiconductor devices and method of manufacturing the same, which substantially overcome one or more of the problems due to the limitations and disadvantages of the related art.

It is therefore a feature of an embodiment of the present invention to provide ohmic contacts having different thicknesses for the multilevel semiconductor devices.

At least one of the above and other features and advantages of the present invention may be realized by providing a method of making a semiconductor device including forming a first insulating layer on a first semiconductor layer, forming a second semiconductor layer on the first insulating layer, forming a second insulating layer on the second semiconductor layer, forming a contact hole extending through the first and second insulating layers, the contact hole exposing an upper surface the first semiconductor layer and a sidewall of the second semiconductor layer, non-conformally depositing a first preliminary ohmic contact layer in the contact hole and conformally depositing a second preliminary ohmic contact layer and a barrier metal layer in the contact hole.

The first preliminary ohmic contact layer maybe treated to form a first preliminary ohmic contact silicide portion where the preliminary ohmic contact layer is in contact with the first semiconductor layer. After treating the first preliminary ohmic contact layer, any of the first preliminary ohmic contact layer remaining may be removed.

At least one of the above and other features and advantages of the present invention may be realized by providing a semiconductor device including a first active semiconductor structure, a first insulating layer on the first active semiconductor structure, a second active semiconductor structure on the first insulating layer, a second insulating layer on the second active semiconductor structure and a contact structure including a first ohmic contact of a first material for the first active semiconductor structure and a second ohmic contact of a second material for the second active semiconductor structure, the first and second materials being different.

The contact structure may include a supplemental ohmic contact of the second material on the first ohmic contact. The contact structure may further include a capping layer on the first ohmic contact.

The first material may be cobalt silicide and the second material may be titanium silicide.

The device may further include a third active semiconductor structure on the second insulating layer and a third insulating layer on the third active semiconductor structure, the contact structure further extending through the third insulating layer. The device may include a third ohmic contact of the second material for the third active semiconductor structure.

At least one of the above and other features and advantages of the present invention may be realized by providing a semiconductor device including a first active semiconductor structure, a first insulating layer on the first active semiconductor structure, a second active semiconductor structure on the first insulating layer and over the first active semiconductor structure, a second insulating layer on the second active semiconductor structure, and a contact structure including a first ohmic contact having a vertical thickness on an upper surface of the first active semiconductor structure and a second ohmic contact of a lateral thickness on a sidewall of the second active semiconductor structure, the vertical thickness being greater than the lateral thickness.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a multilevel semiconductor device according to an embodiment of the present invention;

FIG. 2 illustrates a multilevel semiconductor device according to another embodiment of the present invention;

FIG. 3 illustrates a multilevel semiconductor device according to yet another embodiment of the present invention;

FIG. 4 illustrates a multilevel semiconductor device according to still another embodiment of the present invention, the device including first and second elevated semiconductor layers;

FIGS. 5A-5F illustrate stages in a method of manufacturing the multilevel semiconductor device of FIG. 1;

FIGS. 6A-6C illustrate stages in another method of manufacturing the multilevel semiconductor device of FIG. 1;

FIGS. 7A and 7B illustrate stages in a method of manufacturing the multilevel semiconductor device of FIG. 2;

FIGS. 8A-8C illustrate stages in a method of manufacturing the multilevel semiconductor device of FIG. 3;

FIGS. 9A-9D illustrate stages in a method of manufacturing the multilevel semiconductor device of FIG. 4;

FIG. 10 illustrates a relationship between different embodiments of the present invention and current;

FIG. 11 illustrates a relationship between different embodiments of the present invention and resistance;

FIG. 12 illustrates a relationship between different embodiments of the present invention and a bottom contact resistance; and

FIG. 13 illustrates a relationship between different embodiments of the present invention and a side contact resistance.

### DETAILED DESCRIPTION OF THE INVENTION

Korean Application No. 2005-0049387 filed in the on Jun. 9, 2005, in the Korean Intellectual Property Office, is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A multilevel semiconductor device according to the present invention may include a first active semiconductor structure having a second active semiconductor structure formed thereon and a contact structure connecting the first and second active semiconductor structures. The contact structure may be disposed to contact source/drain regions of the two active semiconductor structures. In particular, the contact structure may form a first ohmic contact with an upper surface, i.e., a vertical surface, of a source/drain region of the first active structure and form a second ohmic contact with a lateral surface of a source/drain region of the second active structure.

The ohmic contacts may be suicides formed in situ. In particular, the in situ formation of the silicide may be achieved by depositing a metal layer, e.g., titanium, on a heavily doped silicon region and then performing a rapid thermal silicidation (RTS) at, e.g., 600-800° C., to induce formation of the metal silicide. Typically, silicon migrates from the heavily doped region to combine with the metal. Accordingly, the formation of a thick silicide region may result in significant migration of silicon from the heavily doped region, which may lead to consumption of the heavily doped region and void formation.

While an increased vertical thickness of the first ohmic contact will significantly affect the current flowing therethrough, since the doping is relatively constant in the vertical direction, the formation of the second ohmic contact using silicidation may result in a lateral consumption of the heavily doped region by the silicidation. This may, in turn, decrease the current flowing through the second ohmic contact. Accordingly, the lateral thickness of the second ohmic contact should be decreased.

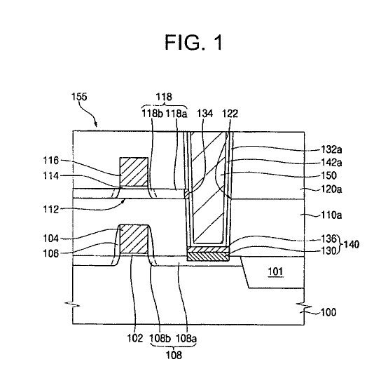

FIG. 1 illustrates a multilevel semiconductor device according to an embodiment of the present invention. The semiconductor device includes a substrate 100, formed, e.g., of silicon (Si), which may be doped with, e.g., p-type dopants or n-type dopants. An isolation region 101 may be formed by, e.g., a shallow trench isolation (STI) process. A gate oxide layer 102, a first gate 104 and gate spacer 106 and a first source/drain region 108 may be formed on the substrate 100. The gate and gate spacer may be formed by, e.g., CVD and dry etch processes. The first source/drain region 108 may include a lightly doped region 108b and a more heavily doped region 108a. A first ILD 110a layer may be formed on the gate 104 and the substrate 100 by, e.g., CVD and CMP processes.

Subsequently, an elevated silicon layer 112 may be formed on the first ILD layer by, e.g., an epitaxial process. A second gate oxide layer 114, a second gate 116 and a second source/drain region 118 may be formed on the elevated silicon layer 112. The second source/drain region 118 may include a lightly doped region 118b and a more heavily doped region 118a.

A second ILD layer 120a may be formed on the second gate 116 and the elevated silicon layer 112.

A contact hole 122 may be formed in the first ILD layer 110a and the second ILD layer 120a, and may extend through the first ILD layer 110a and the second insulating layer 120a. A contact structure may be formed in the contact hole 122 and may include a first ohmic contact 140 and a second ohmic contact 134. The first ohmic contact 140 may be disposed on the first source/drain region 108. The first ohmic contact 140 may include lower and upper ohmic contact layers 130 and 136. The lower ohmic contact layer 130 may be, e.g., a cobalt silicide layer and the upper ohmic contact layer 136 may be, e.g., a titanium silicide layer. The second ohmic contact 134 may be disposed laterally adjacent to the second source/drain region 118 and the second source/drain region 118 may be substantially flush with the contact structure at the second ohmic contact 134. The second ohmic contact 134 may be, e.g., a titanium silicide layer. The contact structure may also include barrier metal regions 132a and 142a formed in the contact hole 122. Barrier metal regions 132a and 142a may be, e.g., titanium and titanium nitride, respectively. A metal layer 150 may be formed on the barrier metal region 142a.

A vertical thickness of the first ohmic contact layer 140 may be greater than a lateral thickness of the second ohmic contact layer 134. The first ohmic contact 140 may be formed of a different material than the second ohmic contact 134. Note that if the vertical thickness of the first ohmic contact 140 is reduced, the contact resistance of the first ohmic region is increased. However, if the lateral thickness of the second ohmic contact layer 134 is reduced, the contact resistance of the second ohmic region is decreased.

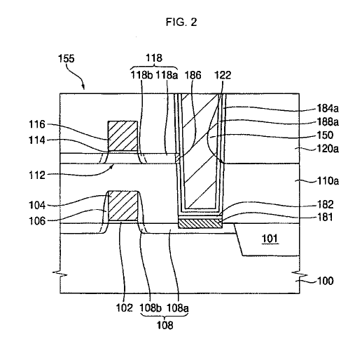

As illustrated in FIG. 2, in another embodiment of the present invention, a multilevel semiconductor device according to the present invention may include a different contact structure formed in the contact hole 122. The embodiment illustrated in FIG. 2 may be similar to the embodiment illustrated in FIG. 1 in other aspects. For example, the multilevel gate structures may be similar, as indicated by the use of like reference numerals to refer to the gates structures of the embodiment illustrated in FIG. 1, although, for clarity, a detailed description of these similar structures will not be repeated.

As illustrated in FIG. 2, in this embodiment the multilevel semiconductor device may include a contact structure having a first ohmic contact 181, e.g., a cobalt silicide layer, disposed on the first source/drain region 108. The contact structure may further include a second ohmic contact region 184a, e.g., a titanium layer, disposed on the sidewalls of the contact hole 122. In contrast to the embodiment illustrated in FIG. 1, this embodiment may also include a capping layer 182 disposed on the first ohmic contact layer 181, such that the first barrier metal region 184a is disposed on the capping layer 182. A second barrier metal region 188a, e.g., a titanium nitride layer, may also be disposed on the sidewalls and bottom of the contact hole 122.

The contact structure illustrated in FIG. 2 may also include a second ohmic contact 186 disposed laterally adjacent to the second source/drain region 118. The second ohmic contact 186 may be, e.g., titanium silicide.

A vertical thickness of the first ohmic contact 181 may be greater than a lateral thickness of the second ohmic contact 186 and the first ohmic contact 181 may be formed of a different material than the second ohmic contact 186.

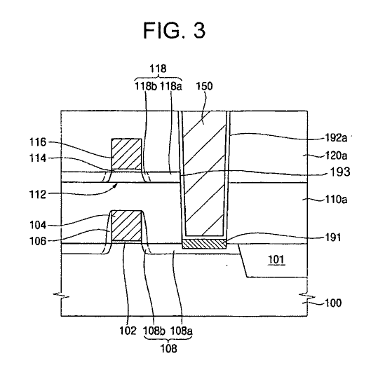

FIG. 3 illustrates a multilevel semiconductor device according to yet another embodiment of the present invention. For clarity, the details of features similar to those already described will be omitted. As in the embodiments illustrated in FIGS. 1 and 2, in this embodiment the multilevel semiconductor device may include a contact structure having a first ohmic contact 191 and a second ohmic contact 193, which may be, e.g., cobalt silicide layers. The contact structure may further include a barrier metal region 192a disposed on the sidewalls of the contact hole 122 and on the first ohmic contact 191. The barrier metal region may be, e.g., a titanium nitride layer.

The first and second ohmic contacts 191 and 193 may be formed by, e.g., non-conformally depositing a material by, e.g., PVD, on the first source/drain region 108 such that there is also a smaller amount of the material deposited on a sidewall of the contact hole 122 adjacent the second source/drain region 118. The material, e.g., cobalt, may then be converted by, e.g., RTS, into ohmic contacts 191 and 193, e.g., cobalt silicide layers. In particular, the use of a non-conformal deposition process may allow the lateral thickness of the second ohmic contact 193 to be less than the vertical thickness of the first ohmic contact 191, e.g., the lateral thickness of the second ohmic contact may be on the order of 10 Å thickness.

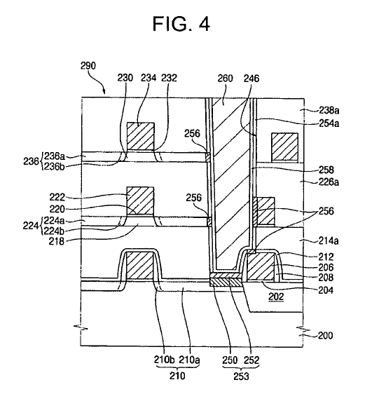

FIG. 4 illustrates a multilevel semiconductor device according to still another embodiment of the present invention, the device including first elevated silicon layer 218 and second elevated silicon layer 230. Substrate 200 may be, e.g., a silicon substrate and may be doped with, e.g., p-type dopants or n-type dopants. An isolation region 202, e.g., a shallow trench isolation region, may be disposed in the substrate 200. A gate oxide layer 204, a first gate 206 and gate spacer 208 may be disposed on the isolation region 202 and may be formed by, e.g., CVD and dry etch processes. A first source/drain region 210 may be formed in the substrate 200 and a first ILD layer 214a may be disposed on the gate 206 and the substrate 200 and may be formed by, e.g., CVD and CMP processes. A capping layer 212 may be formed on the resultant structure.

A first elevated semiconductor layer 218, e.g., a silicon layer, may be disposed on the first ILD layer 214a and may be formed by, e.g., an epitaxial process. A second gate oxide layer 220 and a second gate 222 may be disposed on the first elevated semiconductor layer 218. A second source/drain region 224 may be formed in the first elevated semiconductor layer 218. A second ILD layer 226a may be disposed on the second gate 222 and the first elevated semiconductor layer 218.

A second elevated semiconductor layer 230, e.g., a silicon layer, may be disposed on the second ILD layer 226a and may be formed by, e.g., an epitaxial process. A third gate oxide layer 232 and a third gate 234 may be disposed on the second elevated semiconductor layer 230. A third source/drain region 236 may be formed in the second elevated semiconductor layer 230. A third ILD layer 238a may be disposed on the third gate and the second elevated semiconductor layer 230.

A contact hole 246 may be formed in the first, second and third ILD layers 214a, 226a and 238a, respectively. A first ohmic contact 253 may be disposed on the first source/drain region 210 and one or more other ohmic contacts 256 may be disposed along the sidewalls of the contact hole 246. Ohmic contacts 256 may include, e.g., titanium silicide. One of the ohmic contacts 256 may be disposed laterally adjacent to the second source/drain region 224. The first ohmic contact 253 may include a lower ohmic layer 250, e.g., a cobalt silicide layer, and an upper ohmic layer 252. e.g., a titanium silicide layer. A vertical thickness of the first ohmic contact layer 253 may be greater than a lateral thickness of the other ohmic contact layers 256 and the first ohmic contact layer may include a different material than the second ohmic contact layer 186. A first barrier metal region 254a, e.g., a titanium layer, may be disposed on the sidewalls of the contact hole 246. A second barrier metal region 258 may be formed on the first barrier metal region 254a and a metal layer 260 may be formed on the second barrier metal region 258.

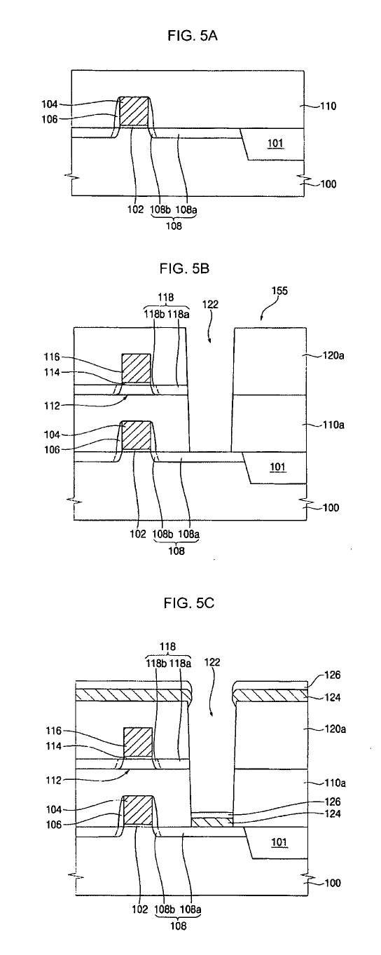

Methods of manufacturing multilevel semiconductor devices according to embodiments of the present invention will now be described. FIGS. 5A-5F illustrate stages in a method of manufacturing the multilevel semiconductor device of FIG. 1. As illustrated in FIG. 5A, the substrate 100, e.g., a semiconductor substrate such as a silicon substrate, is provided. The substrate 100 may be doped with, e.g., p-type or n-type dopants. The isolation region 101 may be formed in the substrate 100 by, e.g., a STI process. The gate oxide layer 102 may be formed on the substrate 100 and the first gate 104 and gate spacer 106 may be formed by, e.g., CVD and dry etch process. The first source/drain region 108, having the heavily doped region 108a and the lightly doped region 108b, may be formed in the substrate 100 by, e.g., an ion implantation process (IIP). A first ILD layer 110 may then be formed on the gate 104 and the substrate 100 by, e.g., CVD and CMP processes.

As illustrated in FIG. 5B, the elevated semiconductor layer 112, e.g., a silicon layer, may be formed by, e.g., an epitaxial or CVD process, on the first ILD layer 110. The second gate oxide layer 114 and the second gate 116 may be formed on the elevated silicon layer 112. The second source/drain region 118 may be formed in the elevated silicon layer 112 and may include the heavily doped region 118a and the lightly doped region 118b. A second ILD layer (not shown) may be formed on the second gate 116 and the elevated silicon layer 112, after which a contact hole 122 may formed from an upper surface 155 through the second ILD layer and the first ILD layer 110. In the illustration, reference numerals 110a and 120a indicate the first and second ILD layers, respectively, after contact hole 122 has been formed therein.

As illustrated in FIG. 5C, a first preliminary ohmic contact layer 124 may be formed in the contact hole 122 and on the second source/drain region 118. The first preliminary ohmic contact layer 124 is preferably a cobalt (Co) layer and may be formed by, e.g., a PVD process. A capping layer 126 may be formed on the first preliminary ohmic contact layer 124. The capping layer 126 may be, e.g., titanium nitride (TiN) and may be formed by, e.g., a PVD process. If a PVD or similar process is used, the first preliminary ohmic contact layer 124 and the capping layer 126 may also be formed on the upper surface 155 of the second ILD layer. However, due to the non-conformal nature of PVD, the first preliminary ohmic contact layer 124 and the capping layer 126 are, for the most part, not formed on the sidewalls of the contact hole 122. In particular, the first preliminary ohmic contact layer 124 and the capping layer 126 are not formed beside, or lateral to, the first ILD layer 110a and the second ILD layer 120a, excepting possibly a region near the upper surface 155.

As illustrated in FIG. 5D, RTS may be performed on the first preliminary ohmic contact layer 124 and the capping layer 126 on the source/drain region 108 to form the lower ohmic layer 130, e.g., by changing the first preliminary ohmic contact layer 124 of cobalt into cobalt silicide. However, the first preliminary ohmic contact layer 124 and the capping layer on the upper surface 155 of the second ILD layer 120a are not changed into cobalt silicide, and are, instead, removed, e.g., by a wet strip process. The lower ohmic contact layer 130 is not removed by the wet strip process.

As illustrated in FIG. 5E, the second preliminary ohmic contact layer 132 may be formed in the contact hole by, e.g., a conformal process such as CVD. The second preliminary ohmic contact 132 is preferably titanium. Note that, in contrast to the deposition of the first preliminary ohmic contact layer 124 and the capping layer 126, the second preliminary ohmic contact layer is conformally deposited on the sidewalls of the contact hole 122. In particular, the second preliminary ohmic contact layer 132 is deposited on the sidewall of the contact hole 122 beside, or lateral to, the second source/drain region 118. The second preliminary ohmic contact layer 132 beside the second source/drain region 118 may then changed into the second ohmic contact 134, e.g., using RTS to convert titanium into titanium silicide. The RTS may also form the upper ohmic layer 136.

In forming the second ohmic contact 134, the second source/drain region 118 may be consumed by the RTS silicidation process. Accordingly, if the lateral thickness of the second ohmic contact layer 134 is increased significantly, the doped region 118a of the second source/drain region 118 may be consumed, resulting in a decreased current. In forming the first ohmic contact layer 140, the first source/drain region 108 may be consumed by the RTS silicidation process without significantly affecting the current. Thus, a vertical thickness of the first ohmic contact 140 may be greater than a lateral thickness of the second ohmic contact 134.

As illustrated in FIG. 5F, the barrier metal layer 142 may be formed on the second preliminary ohmic contact layer 132. The barrier metal layer 142 may be a titanium nitride (TiN) layer and may be formed by, e.g., a CVD process. The metal layer 150 may then be formed on the barrier metal layer 142. A process such as planarization by CMP may be used to planarize the surface of the multilevel semiconductor device. In the illustrations, first and second barrier metal regions 132a and 142a indicate the second preliminary ohmic contact layer and barrier metal layers 132 and 142, respectively, after planarization.

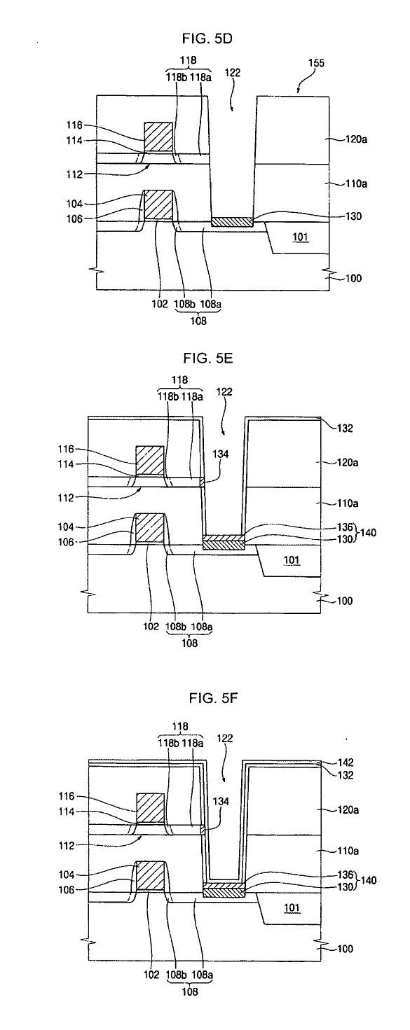

FIGS. 6A-6C illustrate stages in another method of manufacturing the multilevel semiconductor device of FIG. 1. For clarity, the details of formation of features similar to those already described will be omitted. As illustrated in FIG. 6A, the substrate 100 may have the isolation region 101, the gate oxide layer 102, the first gate 104 and gate spacer 106, the first source/drain region 108, the first ILD layer 110a, the elevated semiconductor layer 112, the second gate oxide layer 114, the second gate 116, the second source/drain region 118 and the second ILD layer 120a formed thereon, and the contact hole 122 may be formed in the first and second ILD layers 110a and 120a, respectively. A first preliminary ohmic contact layer 160 may be formed in the contact hole 122 and on the second S/D region 120a. The first preliminary ohmic contact layer 160 is preferably a cobalt layer and may be formed by a non-conformal deposition process such as PVD.

As illustrated in FIG. 6B, a second preliminary ohmic contact layer 164 may be formed in the contact hole 122. The second preliminary ohmic contact layer 164 is preferably titanium and may be formed by a conformal process such as CVD. The second preliminary ohmic contact layer may changed by performing RTS into, e.g., a titanium silicide layer at regions on the first source/drain region 108 and beside, or lateral to, the second source/drain region 118 to produce first ohmic contact layer 170 and second ohmic contact layer 166, respectively.

As illustrated in FIG. 6C, a barrier metal layer 172 may be formed on the second preliminary ohmic contact layer 164. The barrier metal layer 172 may be, e.g., a titanium nitride layer and may be formed by a conformal process such as CVD. Next, a metal layer (not shown) may be deposited to fill the contact hole 122 and the surface of the multilevel semiconductor device may be planarized to yield the device illustrated in FIG. 1.

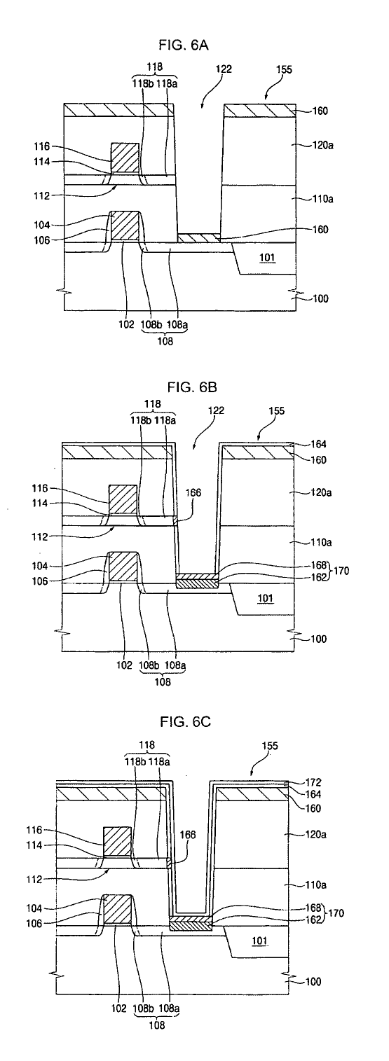

FIGS. 7A and 7B illustrate stages in a method of manufacturing the multilevel semiconductor device of FIG. 2. For clarity, the details of formation of features similar to those already described will be omitted. As illustrated in FIG. 7A, the substrate 100 may have the isolation region 101, the gate oxide layer 102, the first gate 104 and gate spacer 106, the first source/drain region 108, the first ILD layer 110a, the elevated semiconductor layer 112, the second gate oxide layer 114, the second gate 116, the second source/drain region 118 and the second ILD layer 120a is formed thereon, and may have the contact hole 122 is formed in the first and second ILD layers 110a and 120a, respectively. A first preliminary ohmic layer 180 may be formed in the contact hole 122. The first preliminary ohmic layer 180 is preferably a cobalt layer and may be formed by non-conformal process such as PVD. The capping layer 182 may be formed on the first preliminary ohmic layer 180 by, e.g., PVD.

As illustrated in FIG. 7B, a second preliminary ohmic contact layer 184 may be formed in the contact hole 122. The second preliminary ohmic contact layer 184 may be titanium and may be formed by a conformal process such as CVD. A region of the second preliminary ohmic contact layer 184 lateral to the second source/drain region 118 may be changed by RTS to form an ohmic contact layer 186 such as, e.g., a titanium silicide layer. A barrier metal layer (not shown), e.g., a titanium nitride layer may then be formed in the contact hole 122, followed by formation of a metal layer (not shown) filling the contact hole and planarization to yield the device illustrated in FIG. 2.

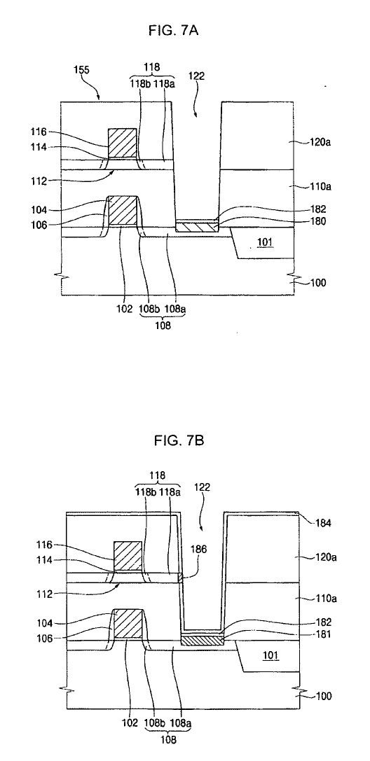

FIGS. 8A-8C illustrate stages in a method of manufacturing the multilevel semiconductor device of FIG. 3. For clarity, the details of formation of features similar to those already described will be omitted. As illustrated in FIG. 8A, the substrate 100 may have the isolation region 101, the gate oxide layer 102, the first gate 104 and gate spacer 106, the first source/drain region 108, the first ILD layer 110a, the elevated semiconductor layer 112, the second gate oxide layer 114, the second gate 116, the second source/drain region 118 and the second ILD layer 120a formed thereon, and the contact hole 122 may be formed in the first and second ILD layers 110a and 120a, respectively. A first preliminary ohmic layer 190 may be formed in the contact hole 122. The first preliminary ohmic layer 190 is preferably a cobalt layer and may be formed by non-conformal process such as PVD. Note that, even though a non-conformal process such as PVD may be used, such that the first preliminary ohmic layer 190 is primarily formed on the first source/drain region 108, a small amount of the first preliminary ohmic layer 190 may also be deposited on a sidewall of the contact hole 122 adjacent to the second source/drain region 118.

As illustrated in FIG. 8B, a barrier metal layer 192 may be formed in the contact hole 122. The barrier metal layer 192 may be, e.g., a titanium nitride layer and may be formed by a conformal process such as CVD.

As illustrated in FIG. 8C, the first preliminary ohmic layer 190 may be changed by RTS to form an ohmic contact layer 191 on the first source/drain region 108 and an ohmic contact layer 193 adjacent to the second source/drain region 118. Ohmic contact layers 191 and 193 may be, e.g., cobalt silicide layers. Formation of a metal layer (not shown) filling the contact hole and planarization may then be performed to yield the device illustrated in FIG. 3.

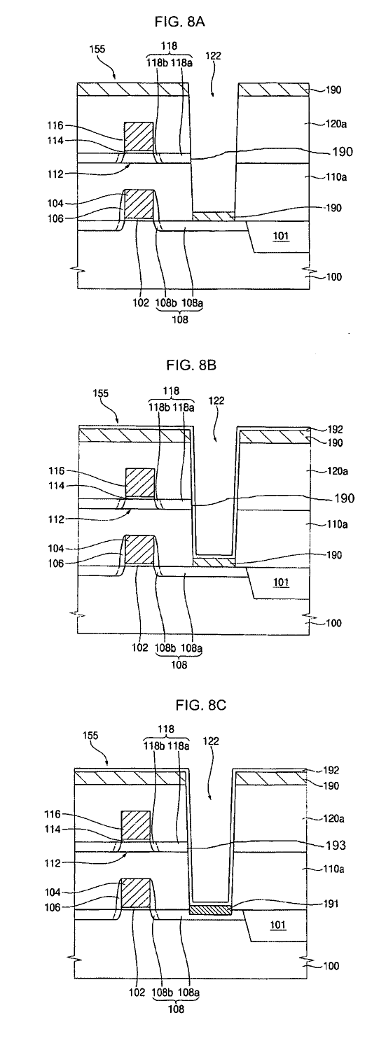

FIGS. 9A-9D illustrate stages in a method of manufacturing the multilevel semiconductor device of FIG. 4. For clarity, the details of formation of features similar to those already described will be omitted. As illustrated in FIG. 9A, the substrate 200 may have the isolation region 202, the gate oxide layer 204, the first gate 206 and gate spacer 208, the first source/drain region 210 formed thereon. The first gate 206 and gate spacer 208 may have a capping oxide layer 212 formed thereon. A first ILD layer 214 may be formed on the gate 206 and the substrate 200 by, e.g., CVD and CMP processes. A first preliminary contact hole 216 may be formed in the first ILD layer 214 exposing first sidewalls 215 of the first ILD layer 214. The first elevated semiconductor layer 218 may be formed on the first ILD layer 214 by, e.g., deposition of silicon using an epitaxial process, and may extend across the first preliminary contact hole 216.

As illustrated in FIG. 9B, the second gate oxide layer 220 may be formed on the first elevated semiconductor layer 218. The second gate 222 and the second source/drain region 224 may be formed on the first elevated semiconductor layer 218. A second ILD layer 226 may be formed on the second gate 22 and the first elevated semiconductor layer 218. A second preliminary contact hole 228 may be formed in the second ILD layer 227 exposing second sidewalls 227 of the first ILD layer 226. The second elevated semiconductor layer 230 may be formed on the second ILD layer 226 by, e.g., deposition of silicon using an epitaxial process, and may extend across the second preliminary contact hole 228. The third gate oxide layer 232, the third gate 234 and the third source/drain region 236 may be formed in the second elevated semiconductor layer 230. A third ILD layer 238 may be formed on the third gate 234 and the second elevated silicon layer 230.

As illustrated in FIG. 9C, a hard mask layer 239 may be formed on the third ILD layer 238. A contact hole 246 may be formed in the first, second and third ILD layers 214, 226 and 238, respectively. The contact hole 246 may be formed using a conventional process, e.g., photolithography and etch, and may encompass the previously formed contact holes 216, 228. In the illustrations, reference numerals 214a, 226a and 238a indicate the first, second and third ILD layers, respectively, after formation of the contact hole 246.

As illustrated in FIG. 9D, the bottom ohmic contact layer 250 may be formed on the first source/drain region 210 by, e.g., non-conformally depositing a preliminary ohmic contact layer, e.g., cobalt (not shown) and converting it by RTS to, e.g., cobalt silicide. A second preliminary ohmic contact layer 254, e.g., a titanium layer, may be formed in the contact hole 246 by, e.g., a conformal deposition process. Regions of the second preliminary ohmic contact layer 254 beside the second source/drain region 224 and the third source/drain region 236 may be changed into side ohmic contact layers 256 by performing RTS to form, e.g., titanium silicide layers. Additionally, a region of the second preliminary ohmic contact layer 254 on the first source/drain region 210 may be changed into an ohmic contact layer 252 by using RTS. Thus, the ohmic contact 253 on the first source/drain region 210 may include, e.g., a cobalt silicide layer 250 and a titanium silicide layer 252. Formation of a metal layer (not shown) filling the contact hole 246 and removal of the hard mask 239 may be performed to complete the multilevel semiconductor device illustrated in FIG. 4.

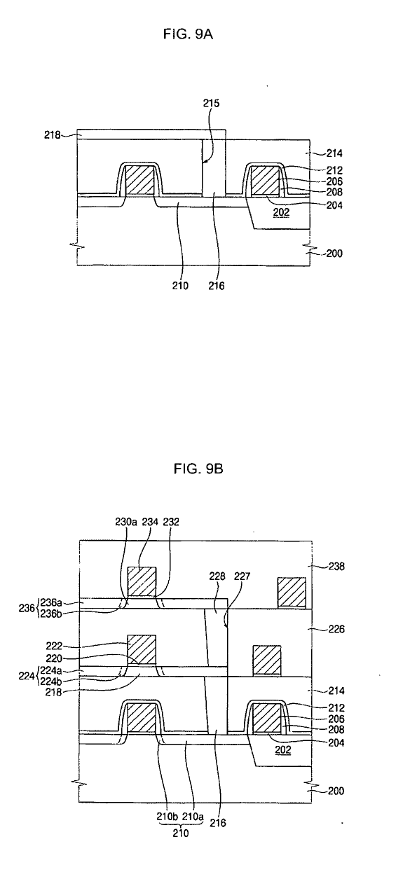

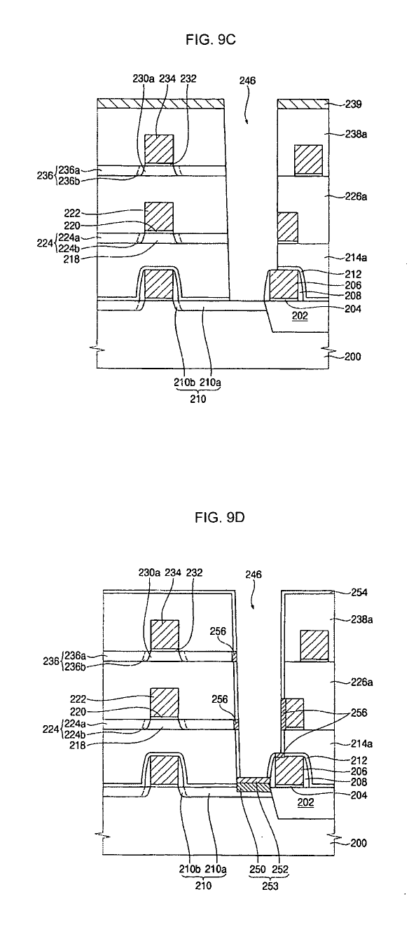

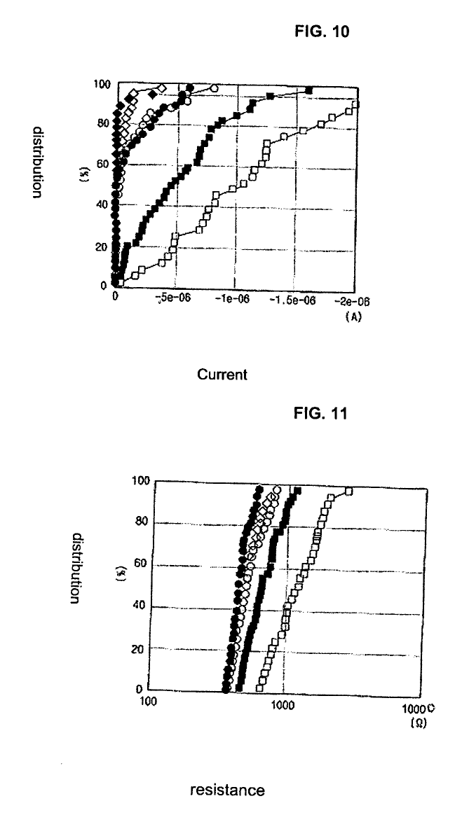

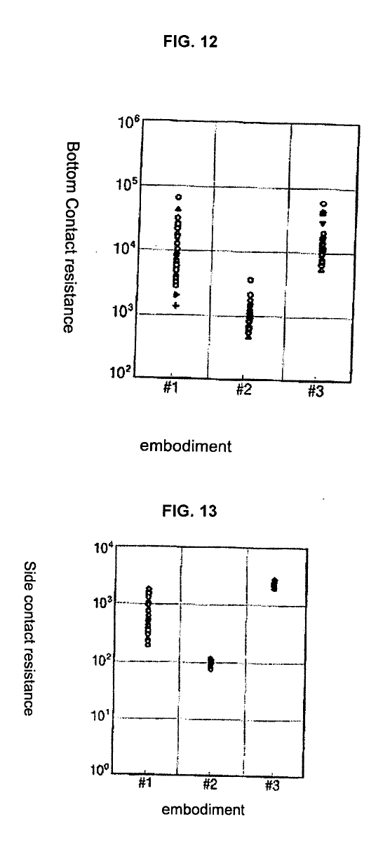

The plots shown in FIGS. 10-13 illustrate that, in accordance with embodiments of the present invention, the ohmic contact for the both sidewall and the bottom allows sufficient current to flow to realize operation of the device. In the plots, embodiment 1 is PVD-Ti 500 Å/CVD-Ti 30 Å, embodiment 2 is PVD-CO 300 Å/CVD-Ti 30 Å and embodiment 3 is CVD-Ti 5 Å.

Thus, in accordance with the present invention, different thicknesses for different ohmic contact regions in a multilevel semiconductor device can be realized. The different thickness may be realized by using different materials applied using different processes.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of making a semiconductor device, comprising:
forming a first insulating layer on a first semiconductor layer;
forming a second semiconductor layer on the first insulating layer;
forming a second insulating layer on the second semiconductor layer;
forming a contact hole extending through the first and second insulating layers, the contact hole exposing an upper surface the first semiconductor layer and a sidewall of the second semiconductor layer;
non-conformally depositing a first preliminary ohmic contact layer in the contact hole; and
conformally depositing a second preliminary ohmic contact layer in the contact hole.

2. The method as claimed in claim 1, further comprising treating the first preliminary ohmic contact layer to form a first metal silicide portion where the first preliminary ohmic contact layer is in contact with the semiconductor layer.

3. The method as claimed in claim 2, further comprising, after treating the first preliminary ohmic contact layer, removing any of the first preliminary ohmic contact layer remaining.

4. The method as claimed in claim 1, wherein the first preliminary ohmic contact layer is cobalt and the second preliminary ohmic contact layer is titanium.

5. The method as claimed in claim 1, wherein a vertical thickness of the first preliminary ohmic contact layer on the upper surface of the first semiconductor layer is greater than a lateral thickness of the second preliminary ohmic contact layer on the sidewall of the second semiconductor layer.

6. The method as claimed in claim 1, wherein conformally depositing the barrier metal layer further forms on the second preliminary ohmic contact layer.

7. A semiconductor device, comprising:
a first active semiconductor structure;
a first insulating layer on the first active semiconductor structure;
a second active semiconductor structure on the first insulating layer;
a second insulating layer on the second active semiconductor structure; and
a contact structure including a first ohmic contact of a first material for the first active semiconductor structure and a second ohmic contact of a second material for the second active semiconductor structure, the first and second materials being different.

8. The device as claimed in claim 7, wherein the contact structure further comprises a supplemental ohmic contact of the second material on the first ohmic contact.

9. The device as claimed in claim 7, wherein the contact structure further comprises a capping layer on the first ohmic contact.

10. The device as claimed in claim 7, wherein the first material is cobalt silicide.

11. The device as claimed in claim 7, wherein the second material is titanium silicide.

12. The device as claimed in 7, further comprising:
a third active semiconductor structure on the second insulating layer; and
a third insulating layer on the third active semiconductor structure, the contact structure further extending through the third insulating layer.

13. The device as claimed in claim 12, further comprising a third ohmic contact of the second material for the third active semiconductor structure.

14. The device as claimed in claim 7, wherein the contact structure further comprises a barrier metal layer covering the first and second ohmic contacts.

15. The device as claimed in claim 14, wherein the contact structure further comprises a barrier metal layer covering the first and second ohmic contacts.

16. The device as claimed in claim 15, wherein the contact structure further comprises a metal filling the contact hole and covering the second barrier metal layer.

17. A semiconductor device, comprising:
a first active semiconductor structure;
a first insulating layer on the first active semiconductor structure;
a second active semiconductor structure on the first insulating layer and over the first active semiconductor structure;
a second insulating layer on the second active semiconductor structure; and
a contact structure including a first ohmic contact having a vertical thickness on an upper surface of the first active semiconductor structure and a second ohmic contact of a lateral thickness on a sidewall of the second active semiconductor structure, the vertical thickness being greater than the lateral thickness.

18. The device as claimed in claim 17, wherein the first and second ohmic contacts are of a different material.
